(19) United States
(12) Patent Application Publication
(10) Pub. No.: US 2025/0089578 A1
(43) Pub. Date: Mar. 13, 2025

(54) MAGNETIC TUNNEL JUNCTION (MTJ) STRUCTURE AND MEMORY CELL

(71) Applicant: Taiwan Semiconductor Manufacturing Company, Ltd., Hsinchu (TW)

(72) Inventors: Zhi-Ren Xiao, Hsinchu County (TW); Nuo Xu, San Jose, CA (US); Po-Sheng Lu, Hsinchu City (TW); Yuan-Hao Chang, Hsinchu (TW); Zhiqiang Wu, Hsinchu County (TW); Yu-Jen WANG, Hsinchu City (TW)

(73) Assignee: Taiwan Semiconductor Manufacturing Company, Ltd., Hsinchu (TW)

(21) Appl. No.: 18/466,004

(22) Filed: Sep. 13, 2023

(51) Int. Cl. H10N 50/85; G11C 11/16; H10B 61/00; H10N 50/10

(52) U.S. Cl. CPC H10N 50/85; G11C 11/161; H10B 61/00; H10N 50/10

(57) ABSTRACT

A magnetic tunnel junction (MTJ) structure and a memory cell are provided. The MTJ includes a barrier layer, a free layer and a metal oxide cap layer. The free layer is disposed on the barrier layer. The metal oxide cap layer is disposed on the free layer. The metal oxide cap layer has a first surface and a second surface opposite to the first surface. The first surface of the metal oxide cap layer is in contact with the free layer. In a direction of a thickness of the metal oxide cap layer, both of an oxygen concentration at the first surface of the metal oxide cap layer and an oxygen concentration at the second surface of the metal oxide cap layer are higher than an oxygen concentration in a middle portion of the metal oxide cap layer.

### BACKGROUND

In the realm of integrated circuit (IC) devices, magnetoresistive random access memory (MRAM) stands as an emerging technology for the next generation of non-volatile memory devices. MRAM encompasses a memory architecture comprising an array of MRAM cells. Each individual MRAM cell consists of a magnetic tunnel junction (MTJ) element, with the resistance of the MTJ element being adjustable to represent either logic “0” or logic “1”. The MTJ element comprises a reference layer and a ferromagnetic free layer, separated by a barrier layer. The resistance of the MTJ element is modulated by altering the magnetic moment's orientation in the ferromagnetic free layer in relation to that of the reference layer. The distinct low and high resistances serve the purpose of indicating a digital signal of “1” or “0”, thereby facilitating data storage.

From an application standpoint, MRAM boasts numerous advantages. Its simple cell structure and compatibility with CMOS logic processes lead to a reduction in manufacturing complexity and costs compared to other non-volatile memory structures. Despite the aforementioned compelling features, several challenges are entwined with MRAM development. Diverse techniques aimed at refining the configurations and materials of these MRAMs have been implemented in a bid to further elevate device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a memory device in accordance with some embodiments of the disclosure.

FIG. 2A to FIG. 2G are cross-sectional views illustrating various stages of a method of manufacturing the memory device in accordance with some embodiments of the disclosure.

FIG. 3A to FIG. 3G are cross-sectional views illustrating various stages of a method of manufacturing a metal oxide cap layer material in accordance with some embodiments of the disclosure.

FIG. 4A and FIG. 4B are cross-sectional views illustrating various stages of another method of manufacturing a metal oxide cap layer material in accordance with some embodiments of the disclosure.

FIG. 5 is a cross-sectional view illustrating a memory device in accordance with some embodiments of the disclosure.

FIG. 6 is a cross-sectional view illustrating a memory device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

A cell within an MRAM device necessitates the ability for current to flow in both directions. Read operations involve the passage of a minor current in a forward direction to gauge the resistance across the MRAM cell. Conversely, write operations entail the traversal of a more substantial current in both forward and reverse directions, facilitating control over the spin orientation of electrons within the free layer of a magnetic tunnel junction (MTJ) housed within the MRAM cell. To illustrate, a memory device rooted in MRAM technology might employ an access transistor to manage the reverse current flow and ultimately dictate the spin orientation of the free layer of the MTJ. Activation of the access transistor can be achieved via a write word line. One terminal of the MRAM cell connects to a bit line, while another terminal links to a select line or read word line. This configuration is recognized as a one-transistor-selector-one-magnetic-tunnel-junction (1T-1MTJ) MRAM cell.

In some MTJ structure, a metal oxide cap layer can be placed over the free layer, serving as a perpendicular magnetic anisotropy (PMA) enhancement layer that works in conjunction with the free layer to exhibit robust PMA characteristics. However, it's noteworthy that the metal oxide cap layer is typically composed of oxides with high resistivity, consequently causing an increase in the overall resistance of the MTJ. As a result, the MTJ requires more currents for proper operation.

In some embodiments disclosed herein, adjustments to the oxygen concentration distribution within the metal oxide cap layer enable the cap layer to enhance the PMA of the free layer without introducing excessive additional resistance to the MTJ. In some cases, the oxygen concentration near the top and bottom surfaces of the metal oxide cap layer is higher, while the concentration in the middle portion is lower. This approach helps mitigate the issue of increased resistance attributed to the metal oxide cap layer in the embodiments.

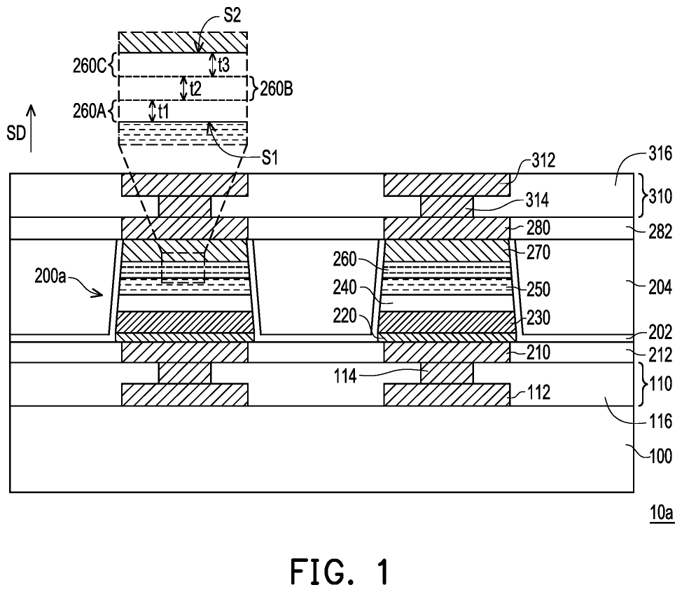

FIG. 1 is a cross-sectional view illustrating a memory device 10a in accordance with some embodiments of the disclosure. The memory device 10a includes a substrate 100, a first redistribution structure 110, MTJ structures 200a (alternatively referred to as memory cells) and a second redistribution structure 310.

In some embodiments, the substrate 100 can be fabricated from semiconductor materials like silicon, silicon germanium, or similar compositions. For example, the substrate 100 may take the form of a crystalline semiconductor substrate, such as crystalline silicon, crystalline silicon carbon, crystalline silicon germanium, or III-V compound semiconductors. In some embodiments, the substrate 100 includes bulk silicon or a silicon-on-insulator (SOI) substrate. Generally, an SOI substrate includes a layer of a semiconductor material such as silicon, germanium, silicon germanium, or combinations thereof, such as silicon germanium on insulator (SGOI). Other substrates that may be used include multi-layered substrates, gradient substrates, or hybrid orientation substrates. In some embodiments, the substrate 100 may be a carrier substrate without any active devices formed therein, such as a glass carrier substrate, a ceramic carrier substrate, or the like.

The first redistribution structure 110 is disposed above the substrate 100. In some embodiments, the first redistribution structure 110 may include an insulating structure 116, commonly in the form of a dielectric material, and metallic structure embedded in the insulating structure 116. In some embodiments, the insulating structure 116 may include an inter-metal dielectric (IMD) layer or an inter-layer dielectric (ILD) layer. Such layers may be composed of a dielectric material featuring a low dielectric constant (k value), potentially lower than 3.8, around 3.0, or even below 2.5.

The insulating structure 116 may be fashioned from diverse substances such as nitrides (e.g., silicon nitride, silicon oxy-nitride, etc.), carbides (e.g., silicon carbide, silicon oxy-carbide etc.), oxides (e.g., silicon dioxide, etc.) or the like.

The first redistribution structure 110 may incorporate metallic pattern like a conductive pattern 112. In some embodiments, conductive vias 114 are utilized to link with the conductive pattern 112, facilitating the electrical connection of the conductive pattern 112 to other conductive components. In some instances, the first redistribution structure 110 includes multiple layers of conductive patterns 112, and the conductive vias 114 serve to electrically interconnect these distinct layers of conductive patterns 112. The configuration of conductive vias 114 and conductive patterns 112 within the first redistribution structure 110 can be adjusted according to requirements.

The bottom electrodes 210 of the MTJ structures 200a are disposed either on or within the first redistribution structure 110. In some embodiments, the bottom electrodes 210 are embedded in the insulating layer 212.

The composition of the bottom electrodes 210 may consist of a solitary layer, while in other embodiments, they may include several distinct layers, composed either of the same material or of differing materials. As examples, the bottom electrodes 210 may include titanium nitride, tantalum nitride, nitrogen, titanium, tantalum, tungsten, cobalt, copper, or similar materials. Alternatively, the bottom electrodes 210 may include a multi-layer structure including at least one of titanium nitride, titanium, tantalum nitride, tantalum, tungsten, and etc.

MTJ stacks are disposed over the bottom electrodes 210. Each MTJ stack includes, from bottom to top, an optional seed layer 220, a reference layer 230, a barrier layer 240, a free layer 250, a metal oxide cap layer 260, and a metallic capping layer 270.

The seed layer 220 is comprised of one or more of NiCr, NiFe, CoFe, CO, Fe, Ni, Ta, Ru, Ti, TaN, Cu, Mg, or other materials typically employed to promote a smooth and uniform grain structure in overlying layers.

The reference layer 230 is disposed over the seed layer 220. The reference layer 230 is a ferromagnetic layer. The reference layer 230 may be formed of a ferromagnetic material alloy such as cobalt iron (CoFe), nickel iron (NiFe), cobalt iron boron (CoFeB), cobalt iron boron tungsten (CoFeBW), or the like. In some embodiments, the reference layer 230 may include two or more ferromagnetic layers separated by a nonmagnetic layer. For example, the reference layer 230 may include a cobalt (Co) film, a molybdenum (Mo) film and an iron-boron (Fe—B) film.

In some embodiments, the reference layer 230 has a magnetization direction that is “hard-biased” (fixed) through ferromagnetic coupling and/or antiferromagnetic coupling. For example, the reference layer 230 can exhibit a synthetic anti-parallel (SyAP) arrangement denoted as AP2/Ru/AP1, wherein an anti-ferromagnetic coupling layer comprised of materials like Ru, Rh, or Ir is sandwiched between an AP2 magnetic layer and an AP1 magnetic layer. The AP2 magnetic layer, also known as the outer magnetic layer, forms atop the seed layer, while the AP1 magnetic layer serves as the inner magnetic layer, typically in contact with the barrier layer 240. AP1 magnetic layer and AP2 magnetic layer may consist of materials like CoFe, CoFeB, Co, or their combinations.

Alternatively, the reference layer 230 may adopt a layered structure with inherent perpendicular magnetic anisotropy (PMA), such as (Co/Ni)n, (CoFe/Ni)n, (Co/NiFe)n, (Co/Pt)n. (Co/Pd)n, or similar stacks, where “n” represents the number of layers in the lamination. Additionally, a transition layer like CoFeB or Co could be introduced between the topmost layer within the layered stack and the barrier layer 240.

The barrier layer 240 is disposed above the reference layer 230. The barrier layer 240 is preferably a metal oxide that is one of MgO, TiOₓ, AlTiO, MgZnO, Al₂O₃, ZnO, ZrOₓ, HfOₓ, or MgTaO, or a lamination of one or more of the aforementioned metal oxides. More preferably, MgO is selected as the barrier layer because it provides high magnetoresistive ratio (DRR).

The free layer 250 is disposed above the barrier layer 240. The free layer 250 is capable of altering its magnetization direction between two distinct states, each corresponding to binary data stored within an MRAM memory cell. To elaborate, in the first state, the magnetization of the free layer 250 aligns parallel to that of the reference layer 230, resulting in a relatively low resistance for the MTJ structure 200a. Conversely, in the second state, the free layer 250 exhibits antiparallel magnetization compared to the reference layer 240, thus yielding a relatively high resistance within the MTJ structure 200a.

Variations in the free layer 250 are possible. It can appear as a single layer in some embodiments or exist as a multilayer structure in others. Additionally, the free layer 250 might comprise two ferromagnetic layers separated by a nonmagnetic layer. For example, the free layer 250 could involve a first ferromagnetic layer positioned over the barrier layer 240, followed by a nonmagnetic layer, and then a second ferromagnetic layer atop the nonmagnetic layer. For instance, the composition of the free layer 250 could involve an iron-boron (Fe—B) film, a manganese (Mg) film, a cobalt-iron (Co—Fe) film and a cobalt-iron-boron (Co—Fe—B) film.

The metal oxide cap layer 260 is disposed on and interfacing with the free layer 250. The metal oxide cap layer 260 may have a thickness ranging from approximately 0.5 nm to approximately 1.3 nm. It may act as a perpendicular-magnetic-anisotropy (PMA) promotion layer. As a result, the free layer 250 exhibits a strong PMA. The metal oxide cap layer 260 is typically a metal oxide layer such as MgO_{y} that has a non-stoichiometric oxidation state so that the resistance is minimized thereby reducing the adverse effect on the highest magnetoresistive ratio (DRR).

The metal oxide cap layer 260 has a first surface S1 and a second surface S2 opposite to the first surface S1. The first surface S1 of the metal oxide cap layer 260 is in contact with the free layer 250. In a direction SD of a thickness of the metal oxide cap layer 260, both of an oxygen concentration at the first surface S1 of the metal oxide cap layer 260 and an oxygen concentration at the second surface S2 of the metal oxide cap layer 260 are higher than an oxygen concentration in a middle portion 260B of the metal oxide cap layer 260. In some embodiments, the metal oxide cap layer 260 includes the lower portion 260A, the middle portion 260B and the upper portion 260C arranged along the direction SD of the thickness of the metal oxide cap layer 260. The lower portion 260A and the upper portion 260C have the first surface S1 and the second surface S2, respectively. An average oxygen concentration of the lower portion 260A and an average oxygen concentration of the upper portion 260C is higher than an average oxygen concentration of the middle portion 260B.

In some embodiments, the oxygen concentration in the metal oxide cap layer 260 decreases from a side (the first surface S1) of the metal oxide cap layer 260 near the free layer 250 to a middle portion 260B of the metal oxide cap layer 260, and then increases from the middle portion 260B of the metal oxide cap layer 260 to another side (the second surface S2) of the metal oxide cap layer 260 away from the free layer 250.

In some embodiments, a material of the metal oxide cap layer 260 includes cubic crystalline MO_{y}, where M is a metallic element (e.g. Mg), O is an oxygen element, and y is in the range of 0.75 to 1 in the lower portion 260A and the upper portion 260C, while y is in the range of 0.5 to 0.75 in the middle portion 260B. In some embodiments, throughout the metal oxide cap layer 260, the average value of y in MO_{y} is greater than 0.68 and less than 0.82 (such as 0.7˜0.73). In some embodiments, the barrier layer 240 and the metal oxide cap layer 260 include the same metal oxide material (e.g. MgO). However, the average oxygen concentration of the metal oxide material in the barrier layer 240 is higher than an average oxygen concentration of the metal oxide material in the metal oxide cap layer 260. For example, the atomic ratio of Mg to O in the barrier layer 240 is approximately 1:1. Such that, a resistivity of the metal oxide cap layer 260 is lower than a resistivity of the barrier layer 240.

In some embodiments, the lower portion 260A and the upper portion 260C each occupy 30% to 40% of a total thickness of the metal oxide cap layer 260, while the middle portion 260B occupies 20% to 40% of the total thickness of the metal oxide cap layer 260. For example, the thickness t1 of the lower portion 260A and the thickness t3 of the upper portion 260C are 2 Å˜5 Å, and the thickness t2 of the middle portion 260B is 1 Å˜3 Å. In some embodiments, the lower portion 260A and the middle portion 260B include an oxygen concentration gradient region with a thickness of approximately 2 Å to 6 Å. Similarly, the upper portion 260C and the middle portion 260B also have an oxygen concentration gradient region with a thickness of approximately 2 Å to 6 Å. The variation in oxygen concentration within the metal oxide cap layer 260, for instance, can occur as either a gradual change or a step-wise change. In some embodiments, the metal oxide cap layer 260 has the oxygen concentration that gradually varies along the stacking direction SD of the MTJ stack.

In the embodiments of the disclosure, by adjusting the oxygen concentration within the metal oxide cap layer 260, the advantages of low resistance can be retained while also imbuing the metal oxide cap layer 260 with the ability to introduce extra interfacial PMA.

The metallic cap layer 270 may be optionally formed above the metal oxide cap layer. The metallic cap layer 270 consists of a non-magnetic transition metal and may encompass one or more elements from the selection of Ta, Ti, V, Cr, Mn, Zr, Nb, Mo, Tc, Ru, Rh, Hf, W, Re, Os, Ir, TiN, TaN, ZrN, HfN, and etc. In some embodiments, the metallic cap layer 270 has a high affinity to oxygen atoms, and may trap oxygen gases during annealing, thereby protecting the MTJ structure 200a from oxygen penetration from ambient processing environments. Without such protection, the oxygen penetration may result in a very high product of resistance and area (RA) and a very low tunnel magnetoresistance (TMR) coefficient. The metallic cap layer 270 can be boron sink for MTJ free layer crystallization, which helps to enhance TMR and PMA.

The dielectric capping layer 202 is disposed on the MTJ stacks. The dielectric capping layer 202 covers sidewalls of the seed layer 220, the reference layer 230, the barrier layer 240, the free layer 250, the metal oxide cap layer 260, and the metallic capping layer 270. In accordance with some embodiments, the dielectric capping layer 202 is formed of silicon nitride, silicon oxynitride, or the like.

The dielectric material 204 is filled into the gaps between the MTJ stacks. The dielectric material 204 may be a TEOS formed oxide, phosphosilicate glass (PSG), borosilicate glass (BSG), boro-phospho-silicate glass (BPSG), undoped silicate glass (USG), fluorinated silicate glass (FSG), SiOCH, flowable oxide, a porous oxide, or the like, or combinations thereof.

The top electrodes 280 are embedded in the insulating layer 282 and disposed above the MTJ stacks. In particular, the top electrodes 280 may be laterally surrounded by an insulating layer 282. In some embodiments, the top electrode 280 is located on the metallic capping layer 270. The top electrodes 280 may be formed using processes and materials similar to the bottom electrodes 210.

The second redistribution structure 310 is disposed above the top electrodes 280. In some embodiments, the second redistribution structure 310 may include an insulating structure 316. The insulating structure 316 may be formed using processes and materials similar to the insulating structure 116.

The second redistribution structure 310 may include metallic pattern like a conductive pattern 312. In some embodiments, conductive vias 314 are utilized to link with the conductive pattern 312, facilitating the electrical connection of the conductive pattern 312 to other conductive components. In some instances, the second redistribution structure 310 includes multiple layers of conductive patterns 312, and conductive vias 314 serve to electrically interconnect these distinct layers of conductive patterns 312. The configuration of conductive vias 314 and conductive patterns 312 within the second redistribution structure 310 can be adjusted according to requirements.

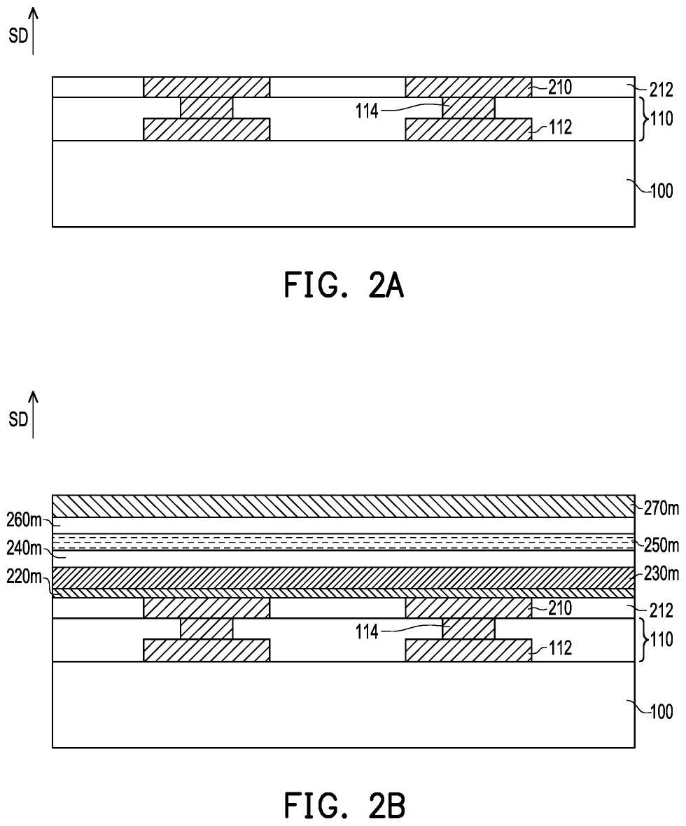

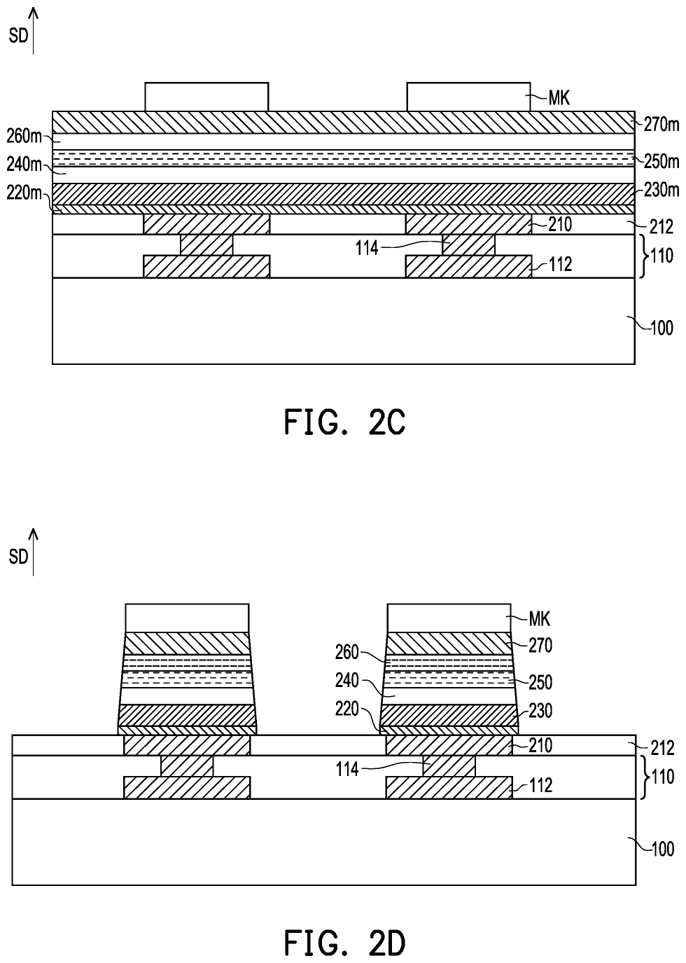

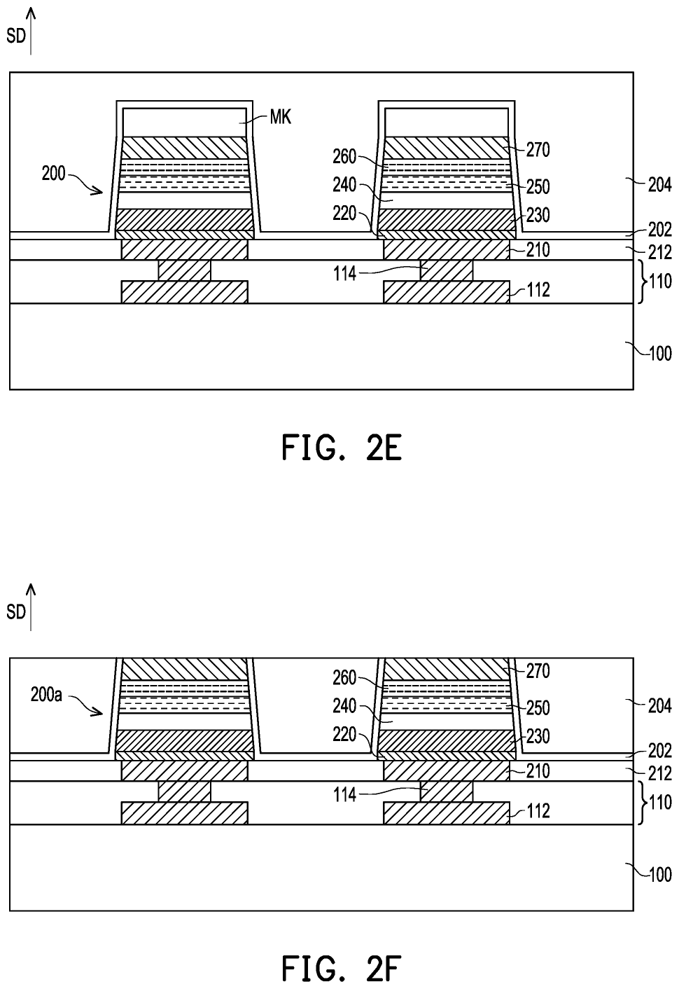

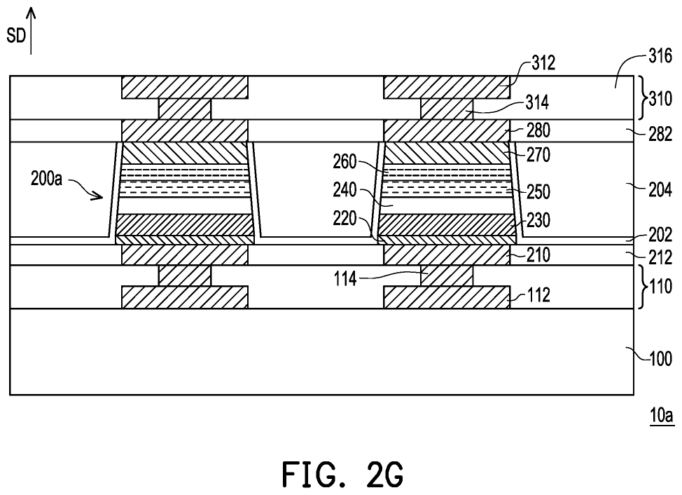

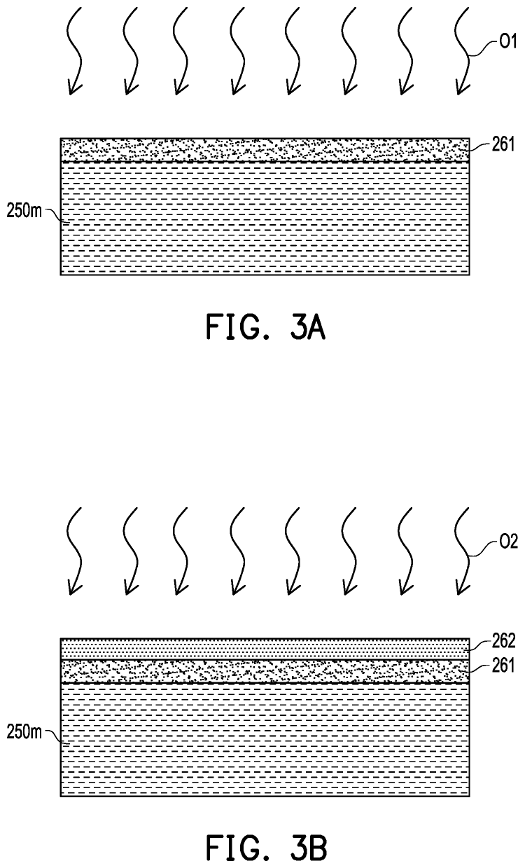

FIG. 2A to FIG. 2G are cross-sectional views illustrating various stages of the method of manufacturing the memory device 10a in FIG. 1. Although FIG. 2A to FIG. 2G are described in relation to methods, it will be appreciated that the structures disclosed in FIG. 2A to FIG. 2G are not limited to such methods, but instead may stand alone as structures independent of the methods.

Referring to FIG. 2A, the first redistribution structure 110 is formed on the substrate 100. The insulating structure 116 of the first redistribution structure 110 may be formed by, for example, chemical vapor deposition (CVD), plasma-enhanced chemical vapor deposition (PECVD), atomic layer deposition (ALD), or the like. In some embodiments, the insulating structure 116 is formed from tetraethyl orthosilicate (TEOS). The conductive vias 114 and the conductive pattern 112 of the first redistribution structure 110 may be deposited by one or more processes such as physical vapor deposition (PVD), CVD, ALD, plating (electrolytic or electroless), a combination thereof, or the like.

The bottom electrodes 210 and the insulating layer 212 is formed on the first redistribution structure 110. In some embodiments, the bottom electrodes 210 may be created through a sequence involving the initial deposition of an insulating layer 212. Subsequently, the insulating layer 212 is patterned to generate openings that expose the conductive vias 114. The subsequent step involves depositing the materials constituting the bottom electrodes 210 within these openings. The insulating layer 212 can be produced and patterned using methodologies and materials akin to those expounded earlier for the insulating structure 116.

As shown in FIG. 2B, a sequential deposition occurs above the bottom electrodes 210 and the insulating layer 212, involving a seed layer material 220m, a reference layer material 230m, a barrier layer material 240m, a free layer material 250m, a metal oxide cap layer material 260m, and a metallic capping layer material 270m. The seed layer material 220m, the reference layer material 230m, the barrier layer material 240m, the free layer material 250m, the metal oxide cap layer material 260m, and the metallic capping layer material 270m are formed by one or more suitable process, such as PVD, CVD. ALD, plating (electrolytic or electroless), a combination thereof, or the like.

Referring to FIG. 2C, a hard mask MK is patterned and used as an etch mask in forming the MTJ stacks. The hard mask MK may be made of any suitable back-end-of-line material for metal hard masks such as titanium nitride, tantalum nitride, or the like. In some embodiments, the hard masks MK may be made of a composition which includes tantalum, tungsten, chromium, ruthenium, molybdenum, silicon, germanium, other MRAM compatible metals, or combinations thereof, such as nitrides and/or oxides of these materials. The hard mask MK may be formed using any suitable process, for example, by PVD, CVD, ALD, and etc.

In FIG. 2D, each of the underlying layers is etched in successive etch steps to form the MTJ stacks corresponding to the MTJ structure 200a as shown in FIG. 1. The etching of each of the layers of the seed layer material 220m, the reference layer material 230m, the barrier layer material 240m, the free layer material 250m, the metal oxide cap layer material 260m, and the metallic capping layer material 270m may be performed using a suitable etchant selective to the particular layer being etched. The etching technique may include wet etching, dry etching, or the like.

In some embodiments, each MTJ stack includes, from bottom to top, an optional seed layer 220, a reference layer 230, a barrier layer 240, a free layer 250, a metal oxide cap layer 260, and a metallic capping layer 270.

FIG. 2E illustrates the formation of the dielectric capping layer 202 and the dielectric material 230 in accordance with some embodiments. In accordance with some embodiments, the dielectric capping layer 202 is formed of silicon nitride, silicon oxynitride, or the like. The formation process may be a CVD process, an ALD process, a plasma enhance CVD (PECVD) process, or the like. The dielectric capping layer 202 may be formed as a conformal layer.

The dielectric material 204 is filled into the gaps between the MTJ stacks. The dielectric material 204 may be a TEOS formed oxide, PSG, BSG, BPSG, USG, FSG, SiOCH, flowable oxide, a porous oxide, or the like, or combinations thereof. The dielectric material 204 may also be formed of a low-k dielectric material. The formation method may include CVD, PECVD, ALD, FCVD, spin-on coating, or the like.

In FIG. 2F, following the gap-filling process, a planarization procedure, such as chemical mechanical polishing (CMP) or mechanical grinding, may be performed. The hard mask layer MK or the metallic capping layer 270 can serve as a CMP stop layer during this planarization process. In this embodiment, the hard mask layer MK is completely removed in the planarization procedure and the upper surface of the dielectric material 204 may align with the upper surface of the metallic capping layer 270. In alternative scenarios, the dielectric capping layer 202 may function as the CMP stop layer.

In FIG. 2G, the top electrodes 280 and the insulating layer 282 are formed. The top electrodes 280 and the insulating layer 282 may be formed using processes and materials similar to the bottom electrodes 210 and the insulating layer 212 as discussed above with respect to FIG. 2A.

The second redistribution structure 310 is formed on the top electrodes 280 and the insulating layer 282. The insulating structure 316 of the second redistribution structure 310 may be formed by, for example, CVD, PECVD, ALD, or the like. In some embodiments, the insulating structure 316 is formed from TEOS. The conductive vias 314 and the conductive pattern 312 of the second redistribution structure 310 may be deposited by one or more processes such as PVD, CVD, ALD, plating (electrolytic or electroless), a combination thereof, or the like.

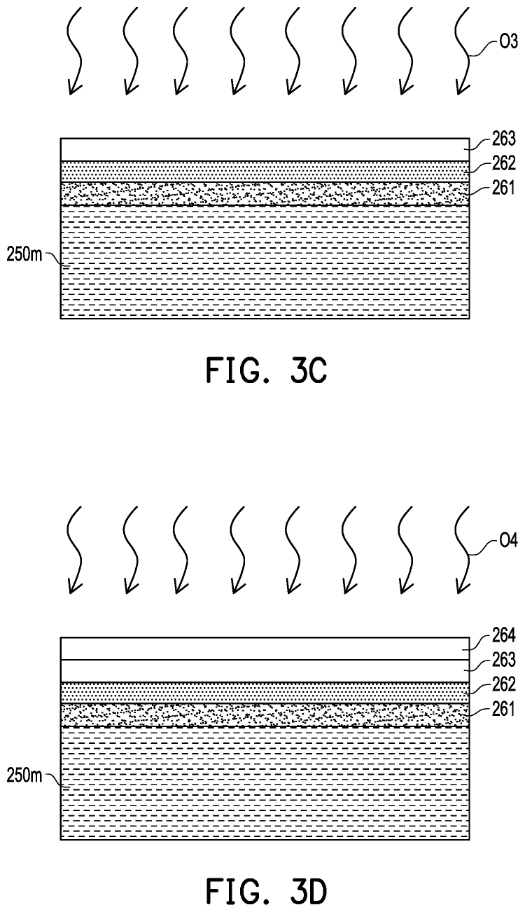

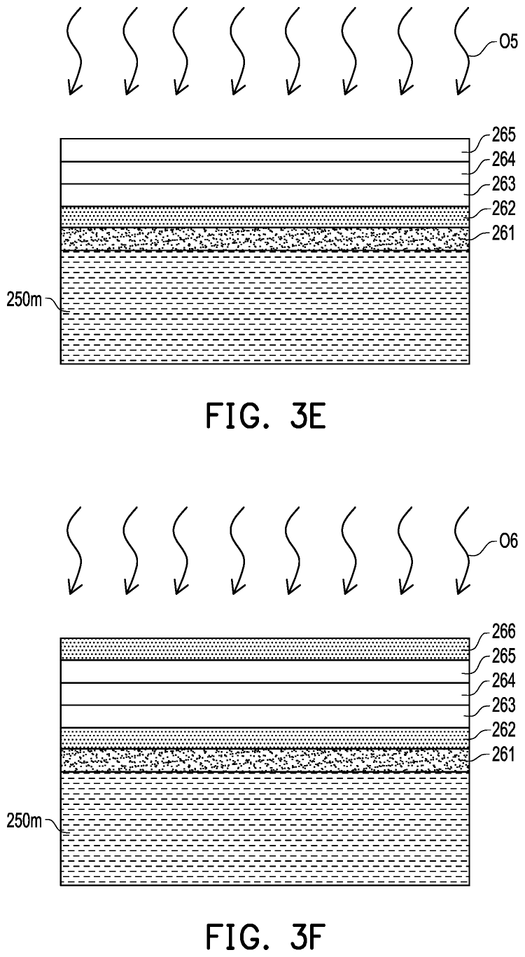

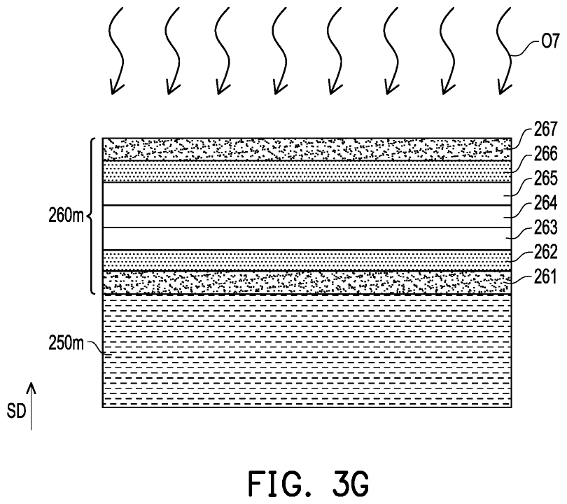

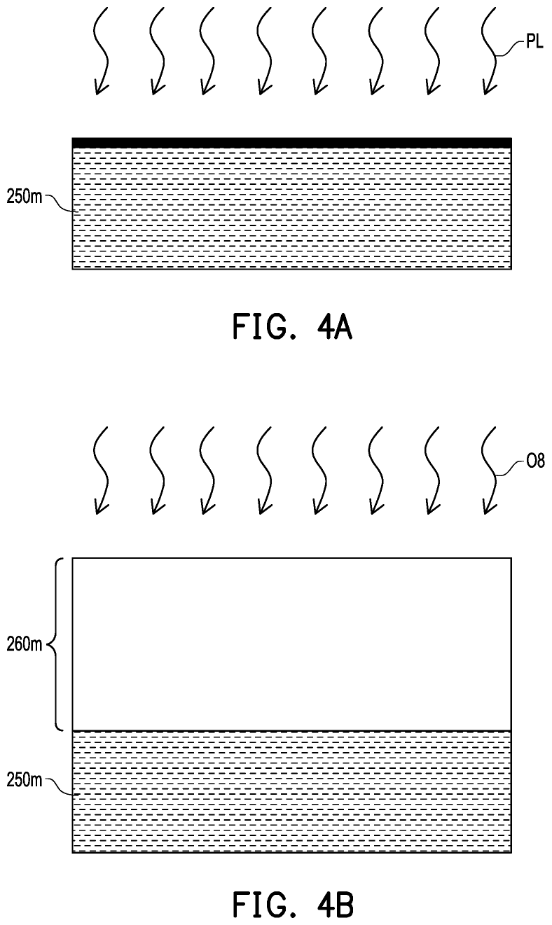

FIG. 3A to FIG. 3G are cross-sectional views illustrating various stages of a method of manufacturing a metal oxide cap layer material 260m in accordance with some embodiments of FIG. 2B. Referring to FIG. 3A, a metal layer (e.g., Mg) is deposited onto the underlying layer (e.g., free layer material 250m), and a first oxidation process O1 is performed to oxidize the aforementioned metal layer so as to form a first layer 261. In some embodiments, the ratio of metal atoms to oxygen atoms in the first layer 261 can be controlled by the flow of gases (e.g., O₂ and/or O₃) used in the first oxidation process O1. For instance, the material of the first layer 261 can be represented as MO_{y1}, where M is a metallic element (e.g., Mg). As the flow of gases (e.g., oxygen and/or ozone) used in the first oxidation process O1 increases, the value of y1 in MO_{y1} becomes larger. In some embodiments, y1 is in a range between 0.75˜1.

In some embodiments, prior to depositing the metal, the underlying layer (e.g., free layer material 250m) is pretreated with oxygen plasma to further enhance the oxygen content in the first layer 261.

Referring to FIG. 3B, a metal layer (e.g., Mg) is deposited onto the underlying layer (e.g., the first layer 261), and a second oxidation process O2 is performed to oxidize the aforementioned metal layer so as to form a second layer 262. In some embodiments, the ratio of metal atoms to oxygen atoms in the second layer 262 can be controlled by the flow of gases (e.g., O₂ and/or O₃) used in the second oxidation process O2. For instance, the material of the second layer 262 can be represented as MO_{y2}, where M is a metallic element (e.g., Mg). In some embodiments, y2 is in a range between 0.75˜1. In some embodiments, y2 in MO_{y2} is less than or equal to y1 in MO_{y1}.

Referring to FIG. 3C, a metal layer (e.g., Mg) is deposited onto the underlying layer (e.g., the second layer 262), and a third oxidation process O3 is performed to oxidize the aforementioned metal layer so as to form a third layer 263. In some embodiments, the ratio of metal atoms to oxygen atoms in the third layer 263 can be controlled by the flow of gases (e.g., O₂ and/or O₃) used in the third oxidation process O3. For instance, the material of the third layer 263 can be represented as MO_{y3}, where M is a metallic element (e.g., Mg). In some embodiments, y3 is in a range between 0.5˜0.75. In some embodiments, y3 in MO_{y3} is less than or equal to y2 in MO_{y2}.

Referring to FIG. 3D, a metal layer (e.g., Mg) is deposited onto the underlying layer (e.g., the third layer 263), and a fourth oxidation process O4 is performed to oxidize the aforementioned metal layer so as to form a fourth layer 264. In some embodiments, the ratio of metal atoms to oxygen atoms in the fourth layer 264 can be controlled by the flow of gases (e.g., O₂ and/or O₃) used in the fourth oxidation process O4. For instance, the material of the fourth layer 264 can be represented as MO_{y4}, where M is a metallic element (e.g., Mg). In some embodiments, y4 is in a range between 0.5˜0.75. In some embodiments, y4 in MO_{y4} is less than or equal to y3 in MO_{y3}.

Referring to FIG. 3E, a metal layer (e.g., Mg) is deposited onto the underlying layer (e.g., the fourth layer 264), and a fifth oxidation process O5 is performed to oxidize the aforementioned metal layer so as to form a fifth layer 266. In some embodiments, the ratio of metal atoms to oxygen atoms in the fifth layer 265 can be controlled by the flow of gases (e.g., O₂ and/or O₃) used in the fifth oxidation process O5. For instance, the material of the fifth layer 265 can be represented as MO_{y5}, where M is a metallic element (e.g., Mg). In some embodiments, y5 is in a range between 0.5˜0.75. In some embodiments, y5 in MO_{y5} is greater than or equal to y4 in MO_{y4}.

Referring to FIG. 3F, a metal layer (e.g., Mg) is deposited onto the underlying layer (e.g., the fifth layer 265), and a sixth oxidation process O6 is performed to oxidize the aforementioned metal layer so as to form a sixth layer 266. In some embodiments, the ratio of metal atoms to oxygen atoms in the sixth layer 266 can be controlled by the flow of gases (e.g., O₂ and/or O₃) used in the sixth oxidation process O6. For instance, the material of the sixth layer 266 can be represented as MO_{y6}, where M is a metallic element (e.g., Mg). In some embodiments, y6 is in a range between 0.75˜1. In some embodiments, y6 in MO_{y6} is greater than or equal to y5 in MO_{y5}.

Referring to FIG. 3D, a metal layer (e.g., Mg) is deposited onto the underlying layer (e.g., the sixth layer 266), and a seventh oxidation process O7 is performed to oxidize the aforementioned metal layer so as to form a seventh layer 267. In some embodiments, the ratio of metal atoms to oxygen atoms in the seventh layer 267 can be controlled by the flow of gases (e.g., O₂ and/or O₃) used in the seventh oxidation process O7. For instance, the material of the seventh layer 267 can be represented as MO_{y7}, where M is a metallic element (e.g., Mg). In some embodiments, y7 is in a range between 0.75˜1. In some embodiments, y7 in MO_{y7} is less than or equal to y6 in MO_{y6}.

In this embodiment, the method of forming the metal oxide cap layer material 260m includes 7 metal deposition processes and 7 oxidation processes, but this disclosure is not limited thereto. In other embodiments, the number of metal deposition processes and oxidation processes used to form the metal oxide cap layer material 260m can be adjusted according to specific requirements. In other words, the metal oxide cap layer material 260m can comprise fewer than 7 layers or more than 7 layers. In this embodiment, by adjusting the first oxidation process O1 through the seventh oxidation process O7, variations in oxygen concentration are achieved from the first layer 261 to the seventh layer 267. In some instances, the outer layers (e.g., the first layer 261 and the seventh layer 267) exhibit the highest oxygen concentration, while the oxygen concentration is lowest in the intermediate layers (e.g., the fourth layer 264). In some embodiments, the oxygen distribution of the metal oxide cap layer material 260m can be asymmetrical in the stacking direction SD. For example, the region with the lowest oxygen concentration is not necessarily located at the center of the metal oxide cap layer material 260m; however, it is ensured that the region with the lowest oxygen concentration does not appear on the upper surface and the lower surface of the metal oxide cap layer material 260m.

In some embodiments, when the value of y in MO_{y} of the middle layer (e.g., MO_{y4} in the fourth layer 264) is greater than or equal to 0.5, the MTJ structure shows enhanced thermal stability, resulting in a sufficient thermal budget (>103 min at 700K). However, when the value of y in MO_{y} of the middle layer (e.g., MO_{y4} in the fourth layer 264) is less than 0.75, the additional resistance introduced by the metal oxide cap layer can be lower (e.g., less than 1 k ohm). Furthermore, at the interface between the metal oxide cap layer and the free layer (near to the first layer), it is preferable to have the value of y (e.g., y1 of MO_{y1}) in 0.75˜1 to maintain an interface magnetic anisotropy (>0.3 erg/cm²) that ensures high retention.

FIG. 4A and FIG. 4B depict cross-sectional views that illustrate different phases of an alternate process for producing a metal oxide cap layer material 260m of FIG. 2B. In reference to FIG. 4A, the underlying layer (e.g., free layer material 250m) is subjected to oxygen plasma treatment PL, thereby providing oxygen atoms to the surface of the underlying layer.

Next, refer to FIG. 4B, where a metal layer (e.g., Mg) is subsequently deposited onto the underlying layer (e.g., free layer material 250m). The metal layer reacts with the oxygen atoms on the underlying layer, resulting in oxidation at the bottom of the metal layer. Oxygen atoms on the surface of the underlying layer diffuse into the metal layer, and the oxygen concentration decreases with distance from the surface of the underlying layer. An oxidation process O8 is carried out to oxidize the previously partially oxidized metal layer, so as to form the metal oxide cap layer material 260m. The oxygen atoms provided by the oxidation process O8 diffuse inward from the top surface of the metal oxide cap layer material 260m. In some embodiments, the ratio of metal atoms to oxygen atoms in the metal oxide cap layer material 260m can be controlled by adjusting the flow of gases (e.g., O₂ and/or O₃) used in the oxidation process O8. Through the combination of oxygen plasma treatment PL and oxidation process O8, the resulting metal oxide cap layer material 260m features higher oxygen concentrations at the top and bottom surfaces while having lower oxygen concentration in the middle portion.

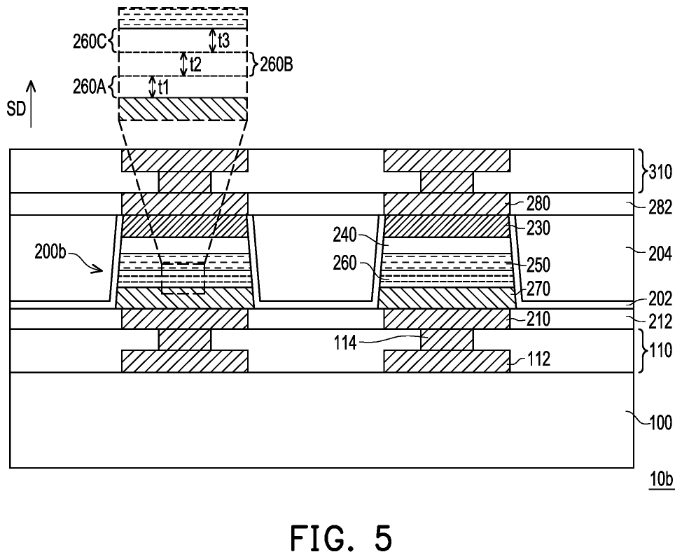

FIG. 5 is a cross-sectional view illustrating a memory device 10b in accordance with some embodiments of the disclosure. It should be noted herein that, in embodiments provided in FIG. 5, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

In FIG. 5, the MTJ structures 200b includes a MTJ stack including, from bottom to top, a metallic capping layer 270, a metal oxide cap layer 260, a free layer 250, a barrier layer 240, and a reference layer 230. In some embodiments, the metallic capping layer 270 is disposed between the metal oxide cap layer 260 and the bottom electrode 210, and the reference layer 230 is disposed between the barrier layer 240 and the top electrode 280.

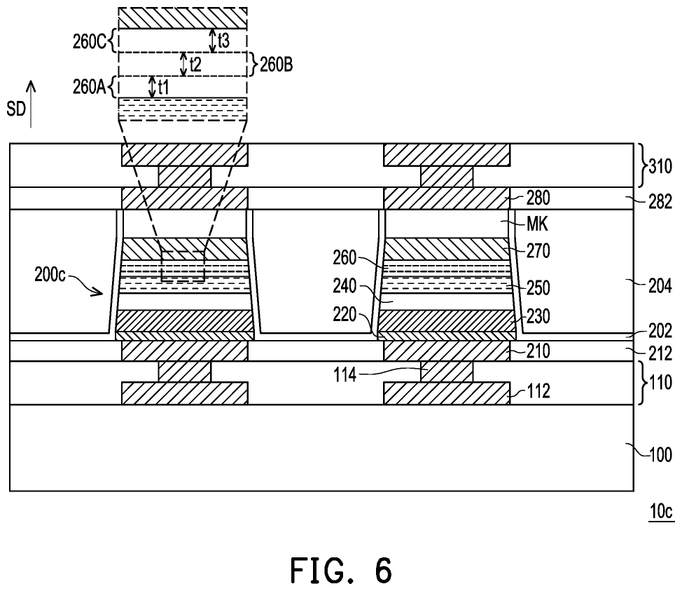

FIG. 6 is a cross-sectional view illustrating a memory device 10c in accordance with some embodiments of the disclosure. It should be noted herein that, in embodiments provided in FIG. 6, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

In FIG. 6, the MTJ structures 200c further includes a hard mask MK disposed between the metallic capping layer 270 and the top electrode 280. In some embodiments, during the process of fabricating MTJ structures 200c, the planarization procedure (refer to FIG. 2F) does not completely remove the hard mask MK, resulting in at least a portion of the hard mask MK being retained on the metallic capping layer 270.

Accordingly, in some embodiments, the present disclosure relates to an MTJ structure including a barrier layer, a free layer and a metal oxide cap layer. The free layer is disposed on the barrier layer. The metal oxide cap layer is disposed on the free layer. The metal oxide cap layer has a first surface and a second surface opposite to the first surface. The first surface of the metal oxide cap layer is in contact with the free layer. In a direction of a thickness of the metal oxide cap layer, both of an oxygen concentration at the first surface of the metal oxide cap layer and an oxygen concentration at the second surface of the metal oxide cap layer are higher than an oxygen concentration in a middle portion of the metal oxide cap layer.

In other embodiments, the present disclosure relates to an MTJ structure including a barrier layer, a free layer and a metal oxide cap layer. The metal oxide cap layer includes, from bottom to top, a lower portion, a middle portion, and an upper portion, wherein an average oxygen concentration of the middle portion is lower than an average oxygen concentration of the lower portion and an average oxygen concentration of the upper portion. The free layer is directly disposed between the barrier layer and the metal oxide cap layer.

In yet other embodiments, the present disclosure relates to a memory cell including a first electrode, a second electrode and a stack of a barrier layer, a free layer and a metal oxide cap layer. The stack is disposed between the first electrode and the second electrode. In a stacking direction of the stack, an oxygen concentration in the metal oxide cap layer decreases from a side of the metal oxide cap layer near the free layer to a middle portion of the metal oxide cap layer, and then increases from the middle portion of the metal oxide cap layer to another side of the metal oxide cap layer away from the free layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A magnetic tunnel junction (MTJ) structure, comprising:
a barrier layer;
a free layer, disposed on the barrier layer; and
a metal oxide cap layer, disposed on the free layer, wherein the metal oxide cap layer has a first surface and a second surface opposite to the first surface, wherein the first surface of the metal oxide cap layer is in contact with the free layer, and wherein in a direction of a thickness of the metal oxide cap layer, both of an oxygen concentration at the first surface of the metal oxide cap layer and an oxygen concentration at the second surface of the metal oxide cap layer are higher than an oxygen concentration in a middle portion of the metal oxide cap layer.

2. The MTJ structure of claim 1, wherein the metal oxide cap layer comprises a lower portion, the middle portion and an upper portion arranged along the direction of the thickness of the metal oxide cap layer, wherein the lower portion has the first surface, the upper portion has the second surface, and an average oxygen concentration of the lower portion and an average oxygen concentration of the upper portion is higher than an average oxygen concentration of the middle portion.

3. The MTJ structure of claim 2, wherein a material of the metal oxide cap layer comprises cubic crystalline MO_{y}, where M is a metallic element, O is an oxygen element, and y is in the range of 0.75 to 1 in the lower portion and the upper portion, while y is in the range of 0.5 to 0.75 in the middle portion.

4. The MTJ structure of claim 3, wherein throughout the metal oxide cap layer, the average value of y in MO_{y} is greater than 0.68 and less than 0.82.

5. The MTJ structure of claim 2, wherein the lower portion and the upper portion each occupy 30% to 40% of a total thickness of the metal oxide cap layer, while the middle portion occupies 20% to 40% of the total thickness of the metal oxide cap layer.

6. The MTJ structure of claim 1, wherein the barrier layer and the metal oxide cap layer comprise a same metal oxide material, wherein an average oxygen concentration of the metal oxide material in the barrier layer is higher than an average oxygen concentration of the metal oxide material in the metal oxide cap layer.

7. The MTJ structure of claim 1, further comprises:
a metallic cap layer, disposed above the metal oxide cap layer;
a reference layer, disposed below the barrier layer;
a bottom electrode, disposed below the reference layer; and
a top electrode, disposed above the metallic cap layer.

8. The MTJ structure of claim 7, further comprises:
a hard mask layer, disposed between the metallic cap layer and the top electrode.

9. A magnetic tunnel junction (MTJ) structure, comprising:
a barrier layer;
a metal oxide cap layer, wherein the metal oxide cap layer comprises, from bottom to top, a lower portion, a middle portion, and an upper portion, wherein an average oxygen concentration of the middle portion is lower than an average oxygen concentration of the lower portion and an average oxygen concentration of the upper portion; and
a free layer, directly disposed between the barrier layer and the metal oxide cap layer.

10. The MTJ structure of claim 9, wherein a material of the metal oxide cap layer comprises cubic crystalline MO_{y}, where M is a metallic element, O is an oxygen element, and y is in the range of 0.75 to 1 in the lower portion and the upper portion, while y is in the range of 0.5 to 0.75 in the middle portion.

11. The MTJ structure of claim 10, wherein throughout the metal oxide cap layer, the average value of y in MO_{y} is greater than 0.68 and less than 0.82.

12. The MTJ structure of claim 9, wherein the lower portion and the upper portion each occupy 30% to 40% of a total thickness of the metal oxide cap layer, while the middle portion occupies 20% to 40% of the total thickness of the metal oxide cap layer.

13. The MTJ structure of claim 9, wherein the barrier layer and the metal oxide cap layer comprise a same metal oxide material, wherein an average oxygen concentration of the metal oxide material in the barrier layer is higher than an average oxygen concentration of the metal oxide material in the metal oxide cap layer.

14. The MTJ structure of claim 9, further comprises:
a first electrode and a second electrode;
a metallic cap layer, disposed between the metal oxide cap layer and the second electrode;
a reference layer, disposed between the barrier layer and the first electrode; and
a hard mask layer, disposed between the metallic cap layer and the second electrode.

15. A memory cell, comprising:
a first electrode and a second electrode; and
a stack of a barrier layer, a free layer and a metal oxide cap layer, disposed between the first electrode and the second electrode, wherein, in a stacking direction of the stack, an oxygen concentration in the metal oxide cap layer decreases from a side of the metal oxide cap layer near the free layer to a middle portion of the metal oxide cap layer, and then increases from the middle portion of the metal oxide cap layer to another side of the metal oxide cap layer away from the free layer.

16. The memory cell of claim 15, wherein the metal oxide cap layer comprises, from bottom to top, a lower portion, the middle portion and an upper portion, wherein a material of the metal oxide cap layer comprises cubic crystalline MO_{y}, where M is a metallic element, O is an oxygen element, and y is in the range of 0.75 to 1 in the lower portion and the upper portion, while y is in the range of 0.5 to 0.75 in the middle portion.

17. The memory cell of claim 16, wherein throughout the metal oxide cap layer, the average value of y in MO_{y} is greater than 0.68 and less than 0.82.

18. The memory cell of claim 16, wherein the lower portion and the upper portion each occupy 30% to 40% of a total thickness of the metal oxide cap layer, while the middle portion occupies 20% to 40% of the total thickness of the metal oxide cap layer.

19. The memory cell of claim 15, wherein the metal oxide cap layer has the oxygen concentration that gradually varies along the stacking direction.

20. The memory cell of claim 15, wherein the barrier layer and the metal oxide cap layer comprise a same metal oxide material but have different average oxygen concentrations, with a resistivity of the metal oxide cap layer being lower than a resistivity of the barrier layer.
